(19) United States
(12) Patent Application Publication
(10) Pub. No.: US 2026/0068352 A1
(43) Pub. Date: Mar. 5, 2026

(54) METHODS AND ASSEMBLIES FOR DEPOSITING A MOLYBDENUM CHALCOGENIDE

(71) Applicant: ASM IP Holding B.V., Almere (NL)

(72) Inventors: Abhishek Dubey, Leuven (BE); Harsh Vardhan Bana, Leuven (BE)

(21) Appl. No.: 19/313,284

(22) Filed: Aug. 28, 2025

Related U.S. Application Data
(60) Provisional application No. 63/689,295, filed on Aug. 30, 2024.

(51) Int. Cl. H10F 71/00; C23C 16/30; C23C 16/455

(52) U.S. Cl. CPC H10F 71/1385; C23C 16/305; C23C 16/45544

(57) ABSTRACT

The disclosure relates to methods of depositing a molybdenum dichalcogenide on a surface of a semiconductor substrate from a gas phase. The methods utilize an oxygen and halogen comprising molybdenum precursor and, in some embodiments, the deposition methods may be selective. The methods may be cyclic deposition methods, in particular atomic layer deposition methods. The disclosure further relates to a molybdenum dichalcogenide layer deposited according to the methods herein, as well as to semiconductor processing assemblies arranged to execute said methods.

### CROSS-REFERENCE TO RELATED APPLICATION(S)

This application claims the benefit of U.S. Provisional Application 63/689,295 filed on Aug. 30, 2024, the entire contents of which are incorporated herein by reference.

### FIELD

The present disclosure generally relates to methods and assemblies for processing semiconductor substrates. More particularly, the disclosure relates to methods and assemblies for depositing a particular material on a semiconductor substrate.

### BACKGROUND

Molybdenum-containing materials, such as molybdenum disulfide (MoS₂), molybdenum oxide (MoOx), molybdenum nitride and elemental molybdenum are intensively studied for their advantageous properties in electronic device manufacturing. Particularly, MoS₂ is desired as a two-dimensional (2D) transition metal dichalcogenide (TMD) with applications in catalysis and nanoelectronics. Direct deposition of a material to produce a 2D material is challenging in terms of layer continuity. Thus, to enable integration of 2D materials in nanoelectronics, carefully controlled deposition processes, optionally coupled with etching or other modification, are actively developed to enable improved semiconductor devices.

Any discussion, including discussion of problems and solutions, set forth in this section has been included in this disclosure solely for the purpose of providing a context for the present disclosure. Such discussion should not be taken as an admission that any of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter. Various embodiments of the present disclosure relate to methods and semiconductor processing assemblies for depositing a molybdenum dichalcogenide.

In one aspect, a method of depositing a molybdenum dichalcogenide on a semiconductor substrate is disclosed. The method comprises providing the substrate having a first surface in a reaction chamber, contacting the first surface with a gas-phase molybdenum precursor and contacting the first surface with a gas-phase chalcogen precursor. In the method, the molybdenum precursor is a molybdenum oxyhalide.

In some embodiments, the method is a cyclic deposition process.

In some embodiments, the molybdenum precursor and the chalcogen precursor are contacted with the first surface alternately and sequentially.

In some embodiments, the molybdenum dichalcogenide is deposited substantially as a layer having a thickness of 3 nm or less.

In some embodiments, the molybdenum precursor is MoO₂Cl₂.

In some embodiments, the temperature of the reaction chamber is from about 350° C. to about 650° C.

In some embodiments, the chalcogen precursor is selected from sulfur, selenium and tellurium.

In some embodiments, the molybdenum dichalcogenide is selected from a group consisting of MoS₂, MoSe₂ and MoTe₂.

In some embodiments, the chalcogen precursor is selected from a group consisting of H₂S, H₂Se, H₂Te, (CH₃)₂S, (NH₄)₂S, Fe₂S, FeS, dimethylsulfoxide ((CH₃)₂SO), (CH₃)₂Se, (CH₃)₂Te, elemental S, elemental Se and elemental Te.

In some embodiments, a reducing agent is provided into the reaction chamber after contacting the first surface with the molybdenum precursor.

In some embodiments, the substrate comprises a second surface having a different composition than the first surface, and the molybdenum dichalcogenide is deposited selectively on the first surface relative to the second surface.

In some embodiments, the first surface comprises a metal. In some embodiments, the first surface comprises a metal oxide. In some embodiments, the first surface is a high-k surface.

In some embodiments, the second surface comprises silicon. In some embodiments, the second surface comprises silicon and oxygen. In some embodiments, the second surface comprises SiO₂.

In some embodiments, the method further comprises an etch-back step. In some embodiments, the etch-back step is performed by contacting the substrate with reactive species comprising chlorine.

In one aspect, a semiconductor processing assembly is disclosed. The semiconductor processing assembly comprises a first reaction chamber constructed and arranged to hold a substrate having a first surface, an injector system constructed and arranged to provide a molybdenum precursor and a chalcogen precursor into the first reaction chamber in a gas phase to contact the first surface. The semiconductor processing assembly further comprises a molybdenum precursor source constructed and arranged to contain and vaporize a molybdenum precursor and a chalcogen precursor source constructed and arranged to contain and vaporize a chalcogen precursor. The semiconductor processing assembly is constructed and arranged to provide the molybdenum precursor and the chalcogen precursor via the injector system into the first reaction chamber to deposit molybdenum dichalcogenide on the first surface.

In some embodiments, the semiconductor processing assembly comprises a controller configured and arranged to cause the semiconductor processing assembly to provide the molybdenum precursor and the chalcogen precursor into the reaction chamber alternately and sequentially.

In some embodiments, the semiconductor processing assembly further comprises a second reaction chamber constructed and arranged to receive the substrate from the first reaction chamber for etching the deposited molybdenum dichalcogenide from the first surface.

In an additional aspect, a semiconductor processing assembly constructed and arranged to perform a method according to the current disclosure is disclosed.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure.

In the drawings

FIG. 1 is a block diagram of exemplary embodiments of a method according to the current disclosure.

FIG. 2 is a schematic drawing of an embodiment of a semiconductor processing assembly according to the current disclosure.

It will be appreciated that elements in the figures are illustrated for simplicity and clarity, and have not necessarily been drawn to scale. The illustrations presented herein are not meant to be actual views of any particular material, structure, or device, but are merely idealized representations that are used to describe embodiments of the disclosure. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

The current disclosure relates to methods of depositing a molybdenum dichalcogenide on a semiconductor substrate. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substate according to the current disclosure comprises a first surface. In some embodiments, the substrate comprises a first surface and a second surface. In some embodiments, the substrate comprises a second surface having a different composition than the first surface, and the molybdenum dichalcogenide is deposited selectively on the first surface relative to the second surface. Thus, the first surface and the second surface have different material properties, allowing for the selective deposition of a molybdenum dichalcogenide on the first surface. Depending on the workflow, the substrate may comprise a third or a further surface, each having different material properties from the first and second surface, and on which the molybdenum dichalcogenide may or may not be deposited.

In some embodiments, the first surface and the second surface are adjacent to each other.

In some embodiments, the first surface and the second surface have the same orientation, i.e. both surfaces are substantially parallel to the overall substrate surface. In some embodiments, the first surface and the second surface are at an angle to each other. For example, one of the first surface and the second surface may be vertical relative to the overall substrate surface, whereas the other is horizontal (i.e. substantially parallel to the overall substrate surface). In some embodiments, the first surface is a vertical surface and the second surface is a horizontal surface. For example, the first surface may be a sidewall of a gap or a recess in the substrate. The second surface may be the bottom of said gap or recess. The second surface may additionally be the top surface of the gap (i.e. the surface surrounding the gap opening). In some embodiments, the first surface is a horizontal surface and the second surface is a vertical surface. For example, the second surface may be a sidewall of a gap or a recess in the substrate. The first surface may be the bottom of said gap or recess. The first surface may additionally be the top surface of the gap (i.e. the surface surrounding the gap opening).

Some embodiments of the current disclosure relate to a selective deposition processes. Selectivity can be given as a percentage calculated by [(deposition on first surface)−(deposition on second surface)]/(deposition on the first surface). Deposition can be measured in any of a variety of ways. In some embodiments, deposition may be given as the measured thickness of the deposited material. In some embodiments, deposition may be given as the measured amount of material deposited.

In some embodiments, selectivity is greater than about 30%. In some embodiments, selectivity is greater than about 50%. In some embodiments, selectivity is greater than about 75% or greater than about 85%. In some embodiments, selectivity is greater than about 90% or greater than about 93%. In some embodiments, selectivity is greater than about 95% or greater than about 98%. In some embodiments, selectivity is greater than about 99% or even greater than about 99.5%. In embodiments, the selectivity can change over the duration or thickness of a deposition.

In some embodiments, deposition only occurs on the first surface and does not occur on the second surface. In some embodiments, deposition on the first surface of the substrate relative to the second surface of the substrate is at least about 80% selective, which may be selective enough for some particular applications. In some embodiments the deposition on the first surface of the substrate relative to the second surface of the substrate is at least about 50% selective, which may be selective enough for some particular applications. In some embodiments the deposition on the first surface of the substrate relative to the second surface of the substrate is at least about 10% selective, which may be selective enough for some particular applications.

In some embodiments, selective deposition is inherent, and no additional processing steps over those conveniently performed on a substrate are necessary. However, in some embodiments, the second surface may be passivated before depositing molybdenum dichalcogenide on the first surface. Selectivity may be inherent to a certain thickness of deposited molybdenum dichalcogenide, and be lost in case deposition is continued beyond a process-specific threshold. In some embodiments, molybdenum dichalcogenide is deposited on the first surface at a thickness of about 1 nm before deposition on the second surface is detectable. In some embodiments, molybdenum dichalcogenide is deposited on the first surface at a thickness of about 1.5 nm before deposition on the second surface is detectable. In some embodiments, molybdenum dichalcogenide is deposited on the first surface at a thickness of about 2 nm before deposition on the second surface is detectable. In some embodiments, molybdenum dichalcogenide is deposited on the first surface at a thickness of about 2.5 nm before deposition on the second surface is detectable. In some embodiments, molybdenum dichalcogenide is deposited on the first surface at a thickness of about 3 nm before deposition on the second surface is detectable. If thicker material layers are desired, the contrast between the first surface and the second surface may be enhanced though passivating the second surface. Alternatively or in addition, intermittent etch-back phase using, for example plasma, such as chlorine-containing plasma, may be used to keep selectivity.

In some embodiments, the first surface comprises a metal. In some embodiments, the metal is selected from elements of groups 3 to 5 of the periodic table of elements. In some embodiments, the metal is selected from a group consisting of scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), rhenium (Re), ruthenium (Ru), osmium (Os), cobalt (Co), rhodium (Rh), nickel (Ni), palladium (Pd), platinum (Pt), copper (Cu), zinc (Zn), aluminum (Al), gallium (Ga), indium (In), tin (Sn) and bismuth (Bi). In some embodiments, the metal is selected from a group consisting of scandium (Sc), yttrium (Y), titanium (Ti), zirconium (Zr), hafnium (Hf), vanadium (V), niobium (Nb), tantalum (Ta), molybdenum (Mo), tungsten (W), cobalt (Co), nickel (Ni), copper (Cu), zinc (Zn), aluminum (Al) and gallium (Ga). In some embodiments, the first surface comprises, consists essentially of or consists of a metal oxide. In some embodiments, the metal oxide is selected from a group consisting of ScOx, MoOx, HfOx, ZrOx, HfZrOx, AlOx and YOx, wherein Ox denotes a generic oxide without limiting to any particular stoichiometry. In some embodiments, the metal oxide is at least one of ZrO₂, HfO₂, Al₂O₃ and Y₂O₃. In some embodiments, the first surface is a high-k surface, such as ZrOx, HfOx, AlOx or YOx. In some embodiments, the first surface comprises, consists essentially of or consists of a metal nitride. In some embodiments, the first surface comprises, consists essentially of, or consists of, titanium nitride (TiN) or tantalum nitride (TaN). In some embodiments, the first surface comprises, consists essentially of or consists of an elemental metal.

In some embodiments, the second surface comprises silicon. In some embodiments, the second surface comprises silicon and oxygen. In some embodiments, the second surface comprises SiO₂. In some embodiments, the second surface comprises, consists essentially of, or consists of SiO₂. The silicon oxide surface may be a native silicon oxide surface or a thermal silicon oxide surface. In some embodiments, the second surface is a low k surface. By a low k surface is herein meant a surface with a k value smaller than that of silicon oxide. In some embodiments, the low k surface is a SiOC surface, i.e. the surface comprises, consists essentially of, or consists of SiOC. In some embodiments, the low k surface is a SiCN surface, i.e. the surface comprises, consists essentially of, or consists of SiCN. In some embodiments, the low k surface is a SiOCN surface, i.e. the surface comprises, consists essentially of, or consists of SiOCN.

In some embodiments, the first surface is a high k surface and the second surface is a silicon oxide surface. In some embodiments, the first surface is a HfOx surface, such as a HfO₂ surface, and the second surface is a silicon oxide surface. In some embodiments, the first surface is a ZrOx surface, such as a ZrO₂ surface, and the second surface is a silicon oxide surface. In some embodiments, the first surface is an AlOx surface, such as an Al₂O₃ surface, and the second surface is a silicon oxide surface.

In some embodiments, the substrate may be pretreated or cleaned prior to or at the beginning of the selective deposition process. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

The method of depositing a molybdenum dichalcogenide according to the current disclosure comprises providing a substrate having a first surface in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The vapor processing assembly, i.e. a semiconductor processing assembly, may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously. In some embodiments, the reaction chamber is a vertical furnace-type reactor.

The reaction chamber can form part of an atomic layer deposition (ALD) assembly. The reaction chamber can form part of a chemical vapor deposition (CVD) assembly. The deposition assembly may be an ALD or a CVD deposition assembly. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors.

The methods according to the current disclosure comprise contacting the first surface of the substrate with a gas-phase molybdenum precursor and contacting the first surface with a gas-phase chalcogen precursor. In other words, a molybdenum precursor and a chalcogen precursor are provided into the reaction chamber holding the substrate.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. In other instances, the compound or element that results from the chemical reaction does not contain a portion of the reactant (an element or group within the reactant) and therefore the reactant is not a precursor.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions.

The precursors according to the current disclosure are provided into the reaction chamber in a gas phase. In this disclosure, “gas” can include material that is a gas at normal temperature and pressure (NTP), a vaporized solid and/or a vaporized liquid, and can be constituted by a single gas or a mixture of gases, depending on the context. A passivation material precursor may be provided to the reaction chamber in gas phase. A hard mask precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In the method, the molybdenum precursor comprises, consists essentially of, or consists of a molybdenum oxyhalide. In some embodiments, the molybdenum precursor comprises, consists essentially of, or consists of MoO₂Cl₂. In some embodiments, the molybdenum precursor comprises, consists essentially of, or consists of MoOCl₄. In the method, the molybdenum precursor is a molybdenum oxyhalide. In some embodiments, the molybdenum precursor is MoO₂Cl₂. In some embodiments, the molybdenum precursor is MoOCl₄.

In advantageous embodiments of the current disclosure, very thin layers of molybdenum dichalcogenide may be deposited. In some embodiments, the molybdenum dichalcogenide is deposited as 2D material. In the current disclosure, 2D material is to be understood as a layer comprising ideally of a single molecular layer of molybdenum dichalcogenide, such as MoS₂ or MoSe₂. However, the sought after properties of a molybdenum dichalcogenide deposited according to the current disclosure may be achieved also with layers comprising at least partially more than one molecular monolayer of molybdenum dichalcogenide. For example, a 2D molybdenum dichalcogenide layer may contain areas of a single molecular layer of the molybdenum dichalcogenide and areas of two or three molecular layers of the molybdenum dichalcogenide. In certain areas, even more layers can be present.

In some embodiments, the molybdenum dichalcogenide is deposited substantially as a layer having a thickness of 3 nm or less. In some embodiments, the molybdenum dichalcogenide is deposited substantially as a layer having a thickness of 2 nm or less. In some embodiments, the molybdenum dichalcogenide is deposited substantially as a layer having a thickness of 1.8 nm or less. In some embodiments, the molybdenum dichalcogenide is deposited substantially as a layer having a thickness of 1 nm or less. In some embodiments, the molybdenum dichalcogenide is deposited substantially as a layer having a thickness of 0.8 nm.

To control the deposition of the molybdenum dichalcogenide carefully, the precursors, i.e. the molybdenum precursor and the chalcogen precursor, are contacted with the substrate (i.e. provided into the reaction chamber), such as with the first surface of the substrate, sequentially. In other words, the precursors are provided into the reaction chamber one after the other, in order to limit their reactions to the surface of the substrate only. To obtain the advantages of the current disclosure as fully as possible, gas-phase reactions between the precursors are avoided. Therefore, in some embodiments, the reaction chamber is purged between providing the molybdenum precursor and the chalcogen precursor into the reaction chamber.

As used herein, the term “purge” refers to a procedure in which gas-phase precursors and/or gas-phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors. Purging may avoid or at least reduce gas-phase interactions between the two gases reacting with each other. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain or another means of separating the two spaces, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

The thickness of the deposited molybdenum dichalcogenide depends on the number of times the two precursors are contacted with the substrate. In the current disclosure, the reactions between the two precursors are substantially or fully self-limiting, such that extending the time that a precursor is provided into the reaction chamber (i.e. precursor pulse time) does not increase the rate of material growth after a certain threshold. Thus, after the surface of the substrate becomes saturated with a first precursor, no further first precursor is chemisorbed thereon. Similarly, when providing the second precursor after the first precursor, it will react with the available reaction sites of the first precursor on the substrate. After the reaction sites have been exhausted, no more of the second precursor reacts with the substrate or the deposited material, and layer growth stops. In some embodiments, the substrate is contacted with the molybdenum precursor first, i.e. before contacting the substrate with the chalcogen precursor.

The duration of contacting the molybdenum precursor with the substrate, such as with the first surface of the substrate, may vary, depending on the selected deposition conditions. For example, temperature, pressure, gas flow rates and reactor type may influence a suitable contacting time. In some embodiments, at least one of the molybdenum precursor and the chalcogen precursor is provided to the reaction chamber in pulses. In some embodiments, the molybdenum precursor is supplied in pulses and the chalcogen precursor is supplied in pulses, and the reaction chamber is purged between consecutive pulses of molybdenum precursor and chalcogen precursor. A duration of providing molybdenum precursor and/or a chalcogen precursor into the reaction chamber (i.e. molybdenum precursor pulse time and chalcogen precursor pulse time, respectively) may be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of molybdenum precursor or a chalcogen precursor pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, molybdenum precursor pulse time may be at least 5 seconds, or at least 10 seconds. In some embodiments, molybdenum precursor pulse time may be at most 5 seconds, or at most 10 seconds or at most 20 seconds, or at most 30 seconds. In some embodiments, chalcogen precursor pulse time may be at least 5 seconds, or at least 10 seconds, or at least 20 seconds. In some embodiments, chalcogen precursor pulse time may be at most 5 seconds, or at most 10 seconds or at most 20 seconds, or at most 30 seconds.

The pulse times for molybdenum precursor, and for chalcogen precursor vary independently according to process in question. The selection of an appropriate pulse time may depend on the substrate topology. For higher aspect ratio structures, longer pulse times may be needed to obtain sufficient surface saturation in different areas of a high aspect ratio structure. Further, the selected molybdenum precursor and chalcogen precursor chemistries may influence suitable pulsing times. For process optimization purposes, shorter pulse times might be preferred as long as appropriate layer properties can be achieved. In some embodiments, molybdenum precursor pulse time is longer than chalcogen precursor pulse time. In some embodiments, chalcogen precursor pulse time is longer than molybdenum precursor pulse time. In some embodiments, molybdenum precursor pulse time is the same as chalcogen precursor pulse time.

In some embodiments, providing molybdenum precursor and/or a chalcogen precursor into the reaction chamber comprises pulsing the molybdenum precursor and the chalcogen precursor over a substrate. In certain embodiments, pulse times in the range of several minutes may be used for the molybdenum precursor and/or the chalcogen precursor. In some embodiments, molybdenum precursor may be pulsed more than one time, for example two, three or four times, before a chalcogen precursor is pulsed to the reaction chamber. Similarly, there may be more than one pulse, such as two, three or four pulses, of a chalcogen precursor before molybdenum precursor is pulsed (i.e. provided) into the reaction chamber.

In some embodiments, the substrate is contacted with the molybdenum precursor and with the chalcogen precursor sequentially once. In some embodiments, the molybdenum precursor and the chalcogen precursor are provided in the reaction chamber alternately and sequentially. In some embodiments, the substrate is contacted with the molybdenum precursor and with the chalcogen precursor alternately and sequentially twice (i.e. the method contains two deposition cycles). In some embodiments, the substrate is contacted with the molybdenum precursor and with the chalcogen precursor alternately and sequentially three times (i.e. the method contains three deposition cycles). In some embodiments, the substrate is contacted with the molybdenum precursor and with the chalcogen precursor alternately and sequentially at least three times. In some embodiments, the substrate is contacted with the molybdenum precursor and with the chalcogen precursor alternately and sequentially at least five times. In some embodiments, the substrate is contacted with the molybdenum precursor and with the chalcogen precursor alternately and sequentially from about two to about 50 times. In some embodiments, the substrate is contacted with the molybdenum precursor and with the chalcogen precursor alternately and sequentially from about two to about 100 times. In some embodiments, the substrate is contacted with the molybdenum precursor and with the chalcogen precursor alternately and sequentially from about two to about 150 times. In some embodiments, the substrate is contacted with the molybdenum precursor and with the chalcogen precursor alternately and sequentially at least five times or at least ten times.

The number of deposition cycles depends on the desired layer thickness and the growth per cycle of the deposited material, which may depend, for example, on the step coverage of an individual deposition cycle. In some embodiments, the growth speed of the molybdenum dichalcogenide is from about 0.05 nm/cycle to about 0.5 nm/cycle. In some embodiments, the growth speed of the molybdenum dichalcogenide is from about 0.05 nm/cycle to about 0.3 nm/cycle. In some embodiments, the growth speed of the molybdenum dichalcogenide is from about 0.1 nm/cycle to about 0.5 nm/cycle. In some embodiments, the growth speed of the molybdenum dichalcogenide is from about 0.1 nm/cycle to about 0.3 nm/cycle. In some embodiments, the growth speed of the molybdenum dichalcogenide is at least 0.1 nm/cycle. In some embodiments, the growth speed of the molybdenum dichalcogenide is at least 0.2 nm/cycle. In some embodiments, the growth speed of the molybdenum dichalcogenide is at least 0.3 nm/cycle.

In embodiments, in which the precursor pulses are repeated alternately, the process is a cyclic deposition process. In some embodiments, the method is a cyclic deposition process. Generally, in cyclic deposition processes according to the current disclosure, such as atomic layer deposition (ALD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing second precursor into the reaction. Without limiting the current disclosure to any specific theory, ALD may be characterized in by at least partially self-limiting reactions and slower and more controllable layer growth speed compared to CVD or other methods known in the art.

The process according to the current disclosure may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

In some embodiments, the temperature of the reaction chamber is from about 350° C. to about 650° C. In some embodiments, the temperature of the reaction chamber is from about 350° C. to about 650° C. or from about 400° C. to about 550° C. or from about 450° C. to about 550° C. or from about 400° C. to about 500° C. or from about 450° C. to about 500° C.

In some embodiments, the chalcogen precursor is selected from sulfur, selenium and tellurium. In some embodiments, the molybdenum dichalcogenide is selected from a group consisting of MoS₂, MoSe₂ and MoTe₂. In some embodiments, the molybdenum dichalcogenide is selected from a group consisting of MoS₂ and MoSe₂. These molybdenum dichalcogenides may be particularly advantageous, especially as 2D materials, due to their favorable properties in semiconductor applications. Monolayer MoS₂ has a direct bandgap of approximately 1.8 eV, while thicker MoS₂ layers have an indirect bandgap of about 1.29 eV. Monolayer MoSe₂ has a direct bandgap of approximately 1.55 eV, in contrast to thicker MoSe₂ layers having an indirect bandgap of about 1.1 eV. MoSe₂. They both exhibit high electron mobility.

Also, these materials may have applications outside conventional semiconductor applications: For example, both MoS₂ and MoSe₂ display strong photoluminescence due to their direct bandgap, making them suitable for optoelectronic devices, such as light-emitting devices. MoSe₂ exhibits higher electrical conductivity than MoS₂, making it more suitable for applications requiring better electrical performance. MoS₂ may further be used in photodetectors, whereas MoSe₂ may be preferred for applications requiring higher electrical conductivity, such as in batteries and electrochemical devices. Due to its narrower band gap and higher optical absorbance than MoS₂, MoSe₂ can be an ideal candidate for semiconductor optoelectronic and photonic device industry, including OLED displays. Further, molybdenum dichalcogenides deposited according to the current disclosure may find use in solar energy applications and in automotive industry. Molybdenum dichalcogenide deposited according to the current disclosure can be advantageously used in all of the above applications, due to the possibility to obtain extremely thin layers with carefully controlled thickness uniformity and material uniformity. In some embodiments, MoS₂ is used as a transparent electrode. Additionally, such MoS₂ and MoSe₂ deposited according to the current disclosure can also be used in silicon heterojunction solar cells.

In some embodiments, the chalcogen precursor is a sulfur precursor. In some embodiments, the chalcogen precursor is a sulfur precursor and the molybdenum dichalcogenide is molybdenum disulfide. In some embodiments, the chalcogen precursor is a selenium precursor. In some embodiments, the chalcogen precursor is a selenium precursor and the molybdenum dichalcogenide is molybdenum diselenide. In some embodiments, the chalcogen precursor is a tellurium precursor. In some embodiments, the chalcogen precursor is a tellurium precursor and the molybdenum dichalcogenide is molybdenum ditelluride. In some embodiments, the chalcogen reactant comprises hydrogen. In some embodiments, the chalcogen precursor is selected from a group consisting of H₂S, H₂Se, H₂Te, (CH₃)₂S, (NH₄)₂S, Fe₂S, FeS, dimethyl sulfoxide ((CH₃)₂SO), (CH₃)₂Se, (CH₃)₂Te, elemental S, elemental Se and elemental Te. In some embodiments, the chalcogen precursor is selected from a group consisting of H₂S, H₂Se, (CH₃)₂S, (NH₄)₂S, (CH₃)₂Se and (NH₄)₂Se. In some embodiments, the chalcogen precursor is selected from a group consisting of H₂S, H₂Se, (CH₃)₂S, (NH₄)₂S and (CH₃)₂Se.

In some embodiments, a reducing agent is provided into the reaction chamber after contacting the first surface with the molybdenum precursor. In some embodiments, a reducing agent is provided into the reaction chamber before contacting the substrate with the chalcogen precursor. Providing the reducing agent may convert the molybdenum precursor bound to the surface of the substrate into elemental molybdenum. When the chalcogen precursor is contacted with the substrate (i.e. the elemental molybdenum on the substrate surface), elemental molybdenum is converted to molybdenum dichalcogenide. In embodiments, in which the chalcogen precursor is a sulfur precursor, the elemental molybdenum is converted to MoS₂. In embodiments, in which the chalcogen precursor is a selenium precursor, the elemental molybdenum is converted to MoSe₂. In embodiments, in which the chalcogen precursor is a tellurium precursor, the elemental molybdenum is converted to MoTe₂.

In some embodiments, the method further comprises an etch-back step. Etching back can be used, for example, to amend the surface properties, such as roughness, of the deposited molybdenum dichalcogenide. Etching back can be used, for example, to reduce the thickness of the deposited molybdenum dichalcogenide. Etching back can be used, for example, to improve the selectivity of the deposited molybdenum dichalcogenide. In some embodiments, the etch-back step is performed by contacting the substrate with reactive species comprising chlorine. In some embodiments, the etch-back is performed by contacting the substrate with a modification agent to modify the topmost portion of the deposited molybdenum dichalcogenide and subsequently contacting the substrate with a removal agent to remove the modified portion of the deposited molybdenum dichalcogenide. In some embodiments, the modification agent is an oxidizing agent, such as ozone, hydrogen peroxide or reactive species of oxygen. In some embodiments, the removal agent is a sulfur-containing reactant, such as a sulfur hexafluoride (SF₆) or thionyl chloride (SOCl₂). Various other removal agents known in the art may alternatively be used, but sulfur-containing ones may be preferred from quality perspective in minimizing the presence of different elements in the process.

In one aspect, a semiconductor processing assembly is disclosed. The semiconductor processing assembly comprises a first reaction chamber constructed and arranged to hold a substrate having a first surface, an injector system constructed and arranged to provide a molybdenum precursor and a chalcogen precursor into the first reaction chamber in a gas phase to contact the first surface. The semiconductor processing assembly further comprises a molybdenum precursor source constructed and arranged to contain and vaporize a molybdenum precursor and a chalcogen precursor source constructed and arranged to contain and vaporize a chalcogen precursor. The semiconductor processing assembly is constructed and arranged to provide the molybdenum precursor and the chalcogen precursor via the injector system into the first reaction chamber to deposit molybdenum dichalcogenide on the first surface.

In some embodiments, the semiconductor processing assembly comprises a controller configured and arranged to cause the semiconductor processing assembly to provide the molybdenum precursor and the chalcogen precursor into the reaction chamber alternately and sequentially.

In some embodiments, the semiconductor processing assembly further comprises a second reaction chamber constructed and arranged to receive the substrate from the first reaction chamber for etching the deposited molybdenum dichalcogenide from the first surface.

In an additional aspect, a semiconductor processing assembly constructed and arranged to perform a method according to the current disclosure is disclosed.

In one aspect, a semiconductor structure is disclosed. The semiconductor structure is formed by using a method according to the current disclosure.

In one aspect, a semiconductor device is disclosed. The semiconductor device is formed by using a method according to the current disclosure. The semiconductor device may be a logic device, such as a FinFET or a gate-all-around (GAA) device. The semiconductor device may be a memory device, such as a NAND or 3D DRAM device.

### DRAWINGS

The disclosure is further explained by the following exemplary embodiments depicted in the drawings. The illustrations presented herein are not meant to be actual views of any particular material, structure, or assembly, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures, devices and assemblies depicted in the drawings may contain additional elements and details, which may be omitted for clarity.

For the sake of brevity, conventional manufacturing, connection, preparation, and other functional aspects of the methods and assemblies described herein may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

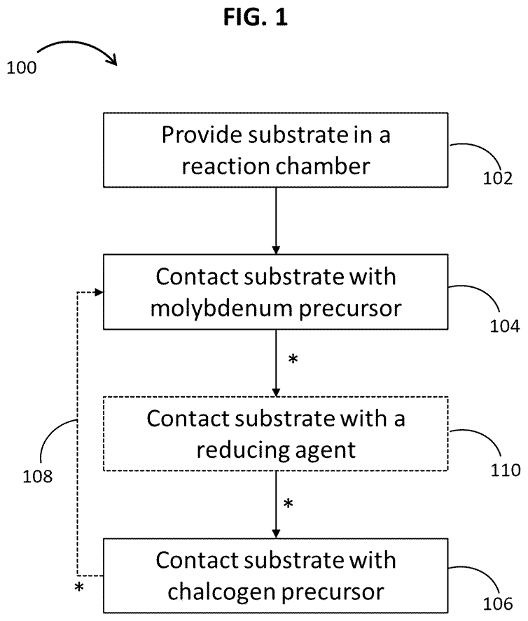

FIG. 1 illustrates exemplary embodiments of a method according to the current disclosure as a block diagram. Method 100 may be used to deposit molybdenum dichalcogenide on a surface of a substrate. In the first phase of the method 102, a substrate comprising a first surface is provided in a reaction chamber. At phase 104, the first surface of the substrate is contacted with a molybdenum precursor. Contacting the first surface of the substrate with the molybdenum precursor is performed by proving the molybdenum precursor into the reaction chamber. At phase 106, the first surface of the substrate is contacted with a chalcogen precursor. Contacting the first surface of the substrate is performed by providing the chalcogen precursor into the reaction chamber.

In embodiments of the disclosure in which the method is a cyclic deposition method, a deposition cycle (i.e. the combination of phases 104 and 106) is repeated for a predetermined number of times (loop 108 in FIG. 1), such that the substrate is contacted by the two precursors multiple times, for example twice, three times, five times, ten times, 50 times or 100 times. A deposition cycle is repeated (loop 108) until a desired layer thickness is achieved. Thus, a deposition cycle may be performed from 1 to about 200 times, for example from 2 to about 200 times, or from about 5 to 200 times. In some embodiments, a deposition cycle is performed from 1 to about 100 times, or from 1 to about 50 times, or from 1 to about 20 times. For example, a deposition cycle may be performed about 5, 30 or 50 times.

When a molybdenum precursor is provided into the reaction chamber, it may chemisorb to the first surface of the substrate. When a chalcogen precursor is provided into the reaction chamber, it may make contact with the molybdenum precursor, or derivates thereof chemisorbed on the first surface of the substrate to form molybdenum dichalcogenide, such as molybdenum disulfide, molybdenum diselenide or molybdenum ditelluride.

In some embodiments, the reaction chamber is purged between consecutive precursor pulses, indicated by an asterisk in FIG. 1. In some embodiments, the reaction chamber is purged after a molybdenum precursor pulse. In some embodiments, the reaction chamber is purged after a chalcogen precursor pulse. In some embodiments, the reaction chamber is purged after a molybdenum precursor pulse and after a chalcogen precursor pulse.

The temperature of the reaction chamber may be selected for the process in question. In some embodiments, the temperature in the reaction chamber is at least 450° C. For example, the temperature in the reaction chamber may be about 500° C. or about 650° C. The temperature of a susceptor holding the substrate may be selected independently of the reaction chamber temperature. In some embodiments, the susceptor temperature is lower than that of the reaction chamber. For example, the temperature of the susceptor may be at least about 450° C.

Methods according to the current disclosure may be performed in reduced pressure. In some embodiments, a pressure in the reaction chamber is below 200 Torr. In some embodiments, a pressure in the reaction chamber is below 100 Torr. In some embodiments, a pressure in the reaction chamber is below 90 Torr. In some embodiments, a pressure in the reaction chamber is at most 100 Torr. In some embodiments, a pressure in the reaction chamber is about 50 Torr, about 60 Torr, about 70 Torr, about 80 Torr, about 90 Torr or about 100 Torr.

In some embodiments, the methods according to the current disclosure are performed in a reducing atmosphere. For example, a hydrogen-comprising gas may be flown into the reaction chamber. In some embodiments, hydrogen-comprising gas is flown into the reaction chamber continuously. In some embodiments, hydrogen-comprising gas is flown into the reaction chamber simultaneously with at least one precursor. In some embodiments, hydrogen-comprising gas is flown into the reaction chamber simultaneously with the molybdenum precursor. In some embodiments, hydrogen-comprising gas is flown into the reaction chamber after a molybdenum precursor pulse. The reducing environment in the reaction chamber during the process according to the current disclosure may at least partially reduce the molybdenum precursor on the substrate into elemental molybdenum. This may be advantageous in forming molybdenum dichalcogenide.

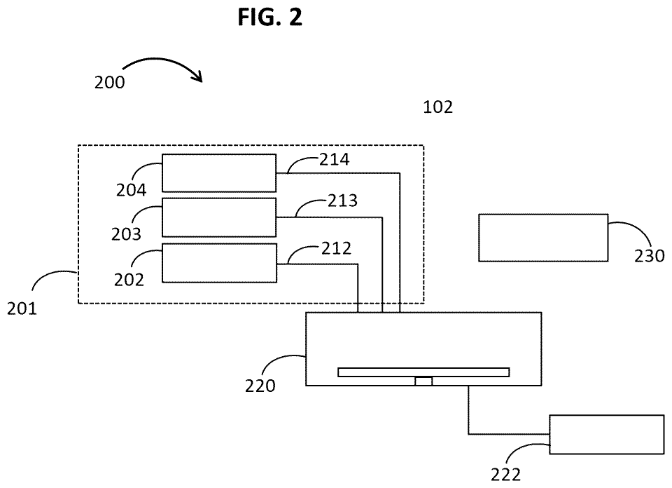

FIG. 2 illustrates a semiconductor processing assembly 200 for depositing a molybdenum dichalcogenide according to the current disclosure in a schematic form. As a schematic representation of a semiconductor processing assembly 200, many components have been omitted for simplicity of illustration, and such components may include, for example, various valves, manifolds, purifiers, heaters, containers, vents, and/or bypasses.

The semiconductor processing assembly 200 comprises one or more reaction chambers 220 constructed and arranged to hold the substrate, a precursor injector system 201 constructed and arranged to provide a molybdenum precursor and a chalcogen precursor into the reaction chamber 220 in gas phase. The semiconductor processing assembly 200 further comprises molybdenum precursor source 202 constructed and arranged to contain the molybdenum precursor and a chalcogen precursor source 203 constructed and arranged to contain the chalcogen precursor. The semiconductor processing assembly 200 is constructed and arranged to provide the molybdenum precursor and the chalcogen precursor from the respective sources 202, 203 into the reaction chamber 220 for depositing molybdenum dichalcogenide on the first surface of the substrate.

The semiconductor processing assembly 200 may comprise one or more optional further reactant sources 204 constructed and arranged to contain additional reactants, such as a reducing agent, used in the processing of the substrate. Only one further reactant source 204 is depicted in FIG. 2 for simplicity. The precursor injector system 201 may be constructed and arranged to provide the one more precursors or additional reactants from a further reactant source 204 into the reaction chamber 220 in a vapor phase. In some embodiments, a further reactant source 204 may be constructed and arranged to hold and vaporize an etchant. For clarity, if an etch step according to the current disclosure comprises using two or more reactants, the current semiconductor processing assembly comprises a suitable number of further reactant sources 204.

The semiconductor processing assembly 200 can be used to perform a method as described herein. In the illustrated example, processing assembly 200 includes one or more reaction chambers 220, a precursor injector system 201, sources 202, 203, 204 as described above, an exhaust source 222, and a controller 230. The processing assembly 200 may comprise one or more additional gas sources (not shown), such as an inert gas source, a carrier gas source and/or a purge gas source. Reaction chamber 220 can include any suitable reaction chamber, such as an ALD or CVD reaction chamber as described herein.

The molybdenum precursor source 202 can include a vessel and a molybdenum precursor as described herein—alone or mixed with one or more carrier (e.g., inert) gases. The chalcogen precursor source 203 can include a vessel and a chalcogen precursor as described herein—alone or mixed with one or more carrier (e.g., inert) gases. Thus, although illustrated with three sources 202-204, a processing assembly 200 can include any suitable number of sources, including suitable vessels. Sources 202-204 can be coupled to reaction chamber 220 via lines 212-214, which can each include flow controllers, valves, heaters, and the like. In some embodiments, each of the sources 202-204 may be independently heated or kept at ambient temperature. In some embodiments, a source vessel is heated so that a precursor or a reactant reaches a suitable temperature for vaporization. For example, in embodiments, in which MoO₂Cl₂ is used as a molybdenum precursor, the molybdenum precursor source 202 may be heated to a temperature of less than 100° C., or to a temperature between 65° C. and 90° C.

Exhaust source 222 can include one or more vacuum pumps.

Controller 230 includes electronic circuitry and software to selectively operate valves, manifolds, heaters, pumps and other components included in the processing assembly 200. Such circuitry and components operate to introduce precursors, reactants and other gases from the respective sources. Controller 230 can control timing of gas pulse sequences, temperature of the substrate and/or reaction chamber 220, pressure within the reaction chamber 220, and various other operations to provide proper operation of the processing assembly 200. Controller 230 can include control software to electrically or pneumatically control valves to control flow of precursors, reactants and other gases into and out of the reaction chamber 220. Controller 230 can include modules such as a software or hardware component, which performs certain tasks.

Other configurations of processing assembly 200 are possible, including different numbers and kinds of sources. For example, a reaction chamber 220 may comprise more than one, such as two or four, deposition stations. Such a multi-station configuration may have advantages if, for example, optional passivation, deposition, reduction and/or etching are to be performed in the same reaction chamber. Further, it will be appreciated that there are many arrangements of valves, conduits, precursor sources, and reactant sources that may be used to accomplish the goal of selectively and in coordinated manner feeding gases into reaction chamber 220. Further, as a schematic representation of a processing assembly 200, many components have been omitted for simplicity of illustration, and such components may include, for example, various valves, manifolds, purifiers, heaters, containers, vents, and/or bypasses.

During operation of processing assembly 200, substrates, such as semiconductor wafers (not illustrated), are transferred from, e.g., a substrate handling system to reaction chamber 220. Once substrate(s) are transferred to reaction chamber 220 (i.e. they are provided in the reaction chamber 220), one or more gases from gas sources, such as precursors, reactants, carrier gases, and/or purge gases, are introduced into reaction chamber 220.

The example embodiments of the disclosure described above do not limit the scope of the disclosure, since these embodiments are merely examples of the embodiments of the methods, structures, devices and processing assemblies, which are defined by the appended claims and their legal equivalents. Any equivalent embodiments are intended to be within the scope of this disclosure. Various modifications of the disclosure, in addition to those shown and described herein, such as alternative useful combinations of the elements described, may become apparent to those skilled in the art from the description. Such modifications and embodiments are also intended to fall within the scope of the appended claims.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject-matter of the present disclosure includes all novel and nonobvious combinations and sub-combinations of the various methods and assemblies, and other features, functions, acts, and/or properties disclosed herein, as well as any and all equivalents thereof.

1. A method of depositing a molybdenum dichalcogenide on a semiconductor substrate, the method comprising
providing the substrate having a first surface in a reaction chamber;
contacting the first surface with a gas-phase molybdenum precursor; and
contacting the first surface with a gas-phase chalcogen precursor,
wherein the molybdenum precursor is a molybdenum oxyhalide.

2. The method of claim 1, wherein the method is a cyclic deposition process.

3. The method of claim 2, wherein the molybdenum precursor and the chalcogen precursor are contacted with the first surface alternately and sequentially.

4. The method of claim 2 having a step coverage of at least 90%.

5. The method of claim 1, wherein the molybdenum dichalcogenide is deposited substantially as a layer having a thickness of 3 nm or less.

6. The method of claim 1, wherein the molybdenum precursor is MoO₂Cl₂.

7. The method of claim 1, wherein temperature of the reaction chamber is from about 350° C. to about 650° C.

8. The method of claim 1, wherein the chalcogen precursor is selected from sulfur, selenium and tellurium.

9. The method of claim 1, wherein the molybdenum dichalcogenide is selected from a group consisting of MoS₂, MoSe₂ and MoTe₂.

10. The method of claim 1, wherein the chalcogen precursor is selected from a group consisting of H₂S, H₂Se, H₂Te, (CH₃)₂S, (NH₄)₂S, Fe₂S, FeS, dimethylsulfoxide ((CH₃)₂SO), (CH₃)₂Se, (CH₃)₂Te, elemental S, elemental Se and elemental Te.

11. The method of claim 1, wherein a reducing agent is provided into the reaction chamber after contacting the first surface with the molybdenum precursor.

12. The method of claim 1, wherein the substrate comprises a second surface having a different composition than the first surface, and the molybdenum dichalcogenide is deposited selectively on the first surface relative to the second surface.

13. The method of claim 12, wherein the first surface comprises a metal.

14. The method of claim 12, wherein the first surface comprises a metal oxide.

15. The method of claim 12, wherein the second surface comprises silicon.

16. The method of claim 12, wherein the second surface comprises SiO₂.

17. The method of claim 1, wherein the method further comprises an etch-back step.

18. A semiconductor processing assembly comprising:
a first reaction chamber constructed and arranged to hold a substrate having a first surface;
an injector system constructed and arranged to provide a molybdenum precursor and a chalcogen precursor into the first reaction chamber in a gas phase to contact the first surface;
wherein the semiconductor processing assembly further comprises
a molybdenum precursor source constructed and arranged to contain and vaporize a molybdenum precursor; and
a chalcogen precursor source constructed and arranged to contain and vaporize a chalcogen precursor, and
wherein the semiconductor processing assembly is constructed and arranged to provide the molybdenum precursor and the chalcogen precursor via the injector system into the first reaction chamber to deposit molybdenum dichalcogenide on the first surface.

19. The semiconductor processing assembly of claim 18 comprising a controller configured and arranged to cause the semiconductor processing assembly to provide the molybdenum precursor and the chalcogen precursor into the first reaction chamber alternately and sequentially.

20. The semiconductor processing assembly of claim 18 further comprising a second reaction chamber constructed and arranged to receive the substrate from the first reaction chamber for etching the deposited molybdenum dichalcogenide from the first surface.
